(19) United States
(12) Patent Application Publication
(10) Pub. No.: US 2007/0099396 A1
(43) Pub. Date: May 3, 2007

(54) METHOD OF FORMING PATTERN, FILM STRUCTURE, ELECTROOPTICAL DEVICE AND ELECTRONIC EQUIPMENT

(75) Inventors: Toshimitsu HIRAI, Suwa (JP); Katsuyuki MORIYA, Suwa (JP); Akira INAGAKI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/552,719

(22) Filed: Oct. 25, 2006

(30) Foreign Application Priority Data
Oct. 27, 2005 (JP) 2005-312302
Sep. 11, 2006 (JP) 2006-245166

(51) Int. Cl. H01L 21/00

(52) U.S. Cl. 438/460; 438/462

(57) ABSTRACT

A method of forming a pattern includes forming mark partition walls that correspond to an alignment mark on a substrate before forming the pattern by providing a pattern forming material between partition walls, and providing a liquid material containing an alignment mark forming material between the mark partition walls.

### BACKGROUND OF THE INVENTION

1. Technical Field

The present invention relates to a method of forming a pattern, a film structure, an electrooptical device and electronic equipment.

2. Related Art

A method of forming a conductive pattern by forming a hydrophilic part and a hydrophobic part on a surface of for example a glass substrate and then providing liquid containing metal particles onto the hydrophilic part has been recently developed. JP-A-2002-164635 is an example of related art. According to the example, the hydrophilic part is firstly formed by forming a hydrophobic film which is composed of organic molecules then removing a part of the hydrophobic film (the hydrophobic part). Subsequently, a conductive pattern is formed by filling a discharge head with a liquid that contains metal particles which are the material of the conductive pattern, then discharging the liquid onto the hydrophilic part as relatively moving the discharge head and a substrate.

Before such liquid discharge method is carried out, a mark called an alignment mark is provided on a substrate. A detection part of the liquid discharge device detects this alignment mark and the substrate is set to a designated position by adjusting the position of the substrate with reference to the alignment mark. In this way, the starting position where the discharge head starts to discharge the liquid is decided.

However, aforementioned technique has the following problem.

Where an alignment mark is formed by using resist and the like, a bank (partition wall) which has a configuration corresponding to the shape of the alignment mark is formed. The bank has a high transparency so that accuracy to recognize the alignment mark is low even with a microscope for alignment such as a CCD camera. This could lower the alignment accuracy,

Particularly where a wiring pattern composed of a stack film is formed or a thin film covering the whole face of a substrate is formed, accuracy to overlay with another layer to form the stack film tends to be lowered.

### SUMMARY

An advantage of the present invention is to provide a method of forming a pattern in which a pattern can be formed with a high alignment precision. Another advantage of the present invention is to provide a film structure, an electrooptical device and electronic equipment manufactured by the pattern forming method.

A method of forming a pattern according to a first aspect of the invention includes forming mark partition walls that correspond to an alignment mark on a substrate before forming the pattern by providing a pattern forming material between partition walls, and providing a liquid material containing an alignment mark forming material between the mark partition walls.

In the method of forming a pattern according to one aspect of the invention, the alignment mark is formed by proving a liquid material containing an alignment mark forming material that has a low transparency between the mark partition walls. Therefore, it is possible to measure the alignment mark with high recognition accuracy This improves the alignment accuracy at the time of patterning and the pattern can be formed at a precise position.

The above described method is particularly effective where the pattern is a wiring pattern.

In this case, it is preferable that the method include a surface treatment process in which the surface of the substrate is treated.

This makes it possible to control the behavior of the droplets provided on the substrate. Accordingly, a desired pattern can be obtained.

It is also preferable that the method include judging an appropriateness of the surface treatment by measuring a length in which the liquid material containing the alignment mark forming material provided between the partition walls extends.

If the surface condition of the substrate is as fine as desired, the drawing can be subsequently carried out. If the surface condition of the substrate is not yet fine, the drawing can be suspended and the substrate can be reproduced. In this way, it is possible to prevent the material from being wasted.

In this case, the partition walls and the mark partition walls may be formed in a same process. Since these walls are simultaneously formed in the same process, the manufacturing efficiency can be improved.

The pattern may include a first pattern and a second pattern that is made of a different material from a material forming the first pattern, and the first pattern and the second pattern are formed in layers. In this case, it is possible to easily form a layered pattern with fine alignment accuracy.

In this case, the alignment mark may be formed of a same material as the material forming the first pattern. In this way, the preparation work can be simplified and the contamination can be prevented.

It is preferable that the first pattern be made of a material having a higher adhesion with the substrate than a material forming the second pattern.

In this way, a layer (interlayer) that imparts the adhesion can be placed in the first layer of the pattern. This improves the adhesion with the substrate and a defect such as coming off from the substrate is not likely to occur.

The method may include forming a semiconductor layer and a pixel electrode by using the alignment mark.

In this way, it is possible to accurately align the wiring pattern with the semiconductor layer and the pixel electrode.

According to a second aspect of the invention, a film structure includes a pattern formed by the above described method of forming a pattern. Since the alignment of the pattern form in the film can be accurately done, it is possible to increase the density of the patterns. In addition, the film structure can be formed at a reduced cost, because it is formed by the droplet discharge method.

According to a third aspect of the invention, an electrooptical device includes the above described film structure. The electrooptical device encompasses a liquid crystal display device, an organic electroluminescence display device and a plasma type display device. According to a fourth aspect of the invention, electronic equipment includes the above described electrooptical device.

According to the third and fourth aspects of the invention, it is possible to provide an electrooptical device and electronic equipment having a high quality pattern at reduced cost.

### BRIEF DESCRIPTION OF THE DRAWINGS

The invention will be described with reference to the accompanying drawings, wherein like numbers reference like elements.

FIG. 1 is an equivalent circuit diagram of a liquid crystal display device showing an embodiment of the invention.

FIG. 2 is a plan view of the liquid crystal display device showing its overall structure.

FIG. 3 is a plan diagram of the liquid crystal display device showing one pixel area.

FIG. 4 is a sectional view of the liquid crystal display device partially showing a TFT array substrate.

FIG. 5A shows an example of a liquid discharge device and FIG. 51B schematically shows a discharge head.

FIG. 6 is a plan view of a substrate in a gate electrode formation process.

FIGS. 7A through 7C are sectional views for explaining steps of a manufacturing method of a TFT array substrate.

FIGS. 8A and 8B are sectional views for explaining steps of the manufacturing method of the TFT array substrate.

FIGS. 9A through 9C are sectional views for explaining steps of the manufacturing method of the TFT array substrate.

FIGS. 10A and 10B are sectional views for explaining steps of the manufacturing method of the TFT array substrate.

FIGS. 11A through 11C are sectional views for explaining steps of the manufacturing method of the TFT array substrate.

FIG. 12 is an exploded perspective view showing an example of a plasma type display device to which an electrooptical device of the invention is applied.

FIGS. 13A through 13C are perspective views of examples of electronic equipment,

FIGS. 14A through 14C are plan views showing other shape examples of an alignment mark.

FIGS. 15A through 15G are plan views showing other shape examples of the alignment mark.

### DESCRIPTION OF EXEMPLARY EMBODIMENTS

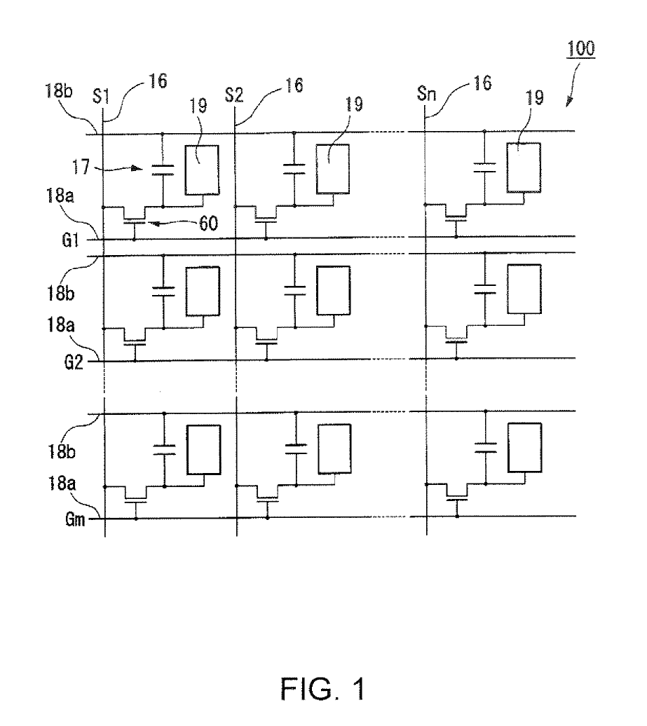

Embodiments of the invention including a method of forming a pattern, a film structure, an electrooptical device and electronic equipment will be described with reference to FIGS. 1 through 14

In the accompanying drawings, a scale size may be different by each member or layer in order to make the member or layer recognizable.

Electrooptical Device

An embodiment of an electrooptical device according to the invention is hereinafter described.

FIG. 1 is an equivalent circuit diagram of a liquid crystal display device 100 which is an embodiment of the electrooptical device of the invention. A plurality of dots that forms an image display area is arranged in matrix in the liquid crystal display device 100. A pixel electrode 19 and a TFT 60 that is a switching element for controlling the pixel electrode 19 are formed in each dot. A data line (electrode wiring) 16 through which an image signal is supplied is electrically coupled to a source of the TFT 60. Image signals S1, S2, . . . , Sn that are to be written into the data lines 16 can be sequentially supplied to each data line or can be provided to each group of the data lines 16 that are arranged next to each other. A scan line (electrode wiring) 18a is electrically coupled to a gate of the TFT 60. Scan signals G1, G2, . . . , Gm are sequentially applied in a pulse form to the corresponding scan lines 18a at a designated timing. The pixel electrode 19 is electrically coupled to a drain of the TFT 60. The image signals S1, S2, . . . , Sn supplied from the data lines 16 are written into the corresponding pixels at a predetermined timing by turning the TFTs 60 which are the switching elements on for a predetermined time period.

The image signals S1 S2, . . . , Sn of a predetermined level written into liquid crystal through the pixel electrodes 19 are retained between the pixel electrodes and a hereinafter described common electrode for a certain period. Light is modulated through variations in the orientation and the alignment of the liquid crystal molecule aggregates which are changed according to the level of the voltage applied to the electrode. Consequently, a tone display is realized. In order to prevent the image signals written into the liquid crystal from leaking, a storage capacitor 17 is added in parallel to liquid crystal capacitance formed between the pixel electrode 19 and the common electrode. Reference number 18b denotes a storage line coupled to the one electrode of the storage capacitor 17.

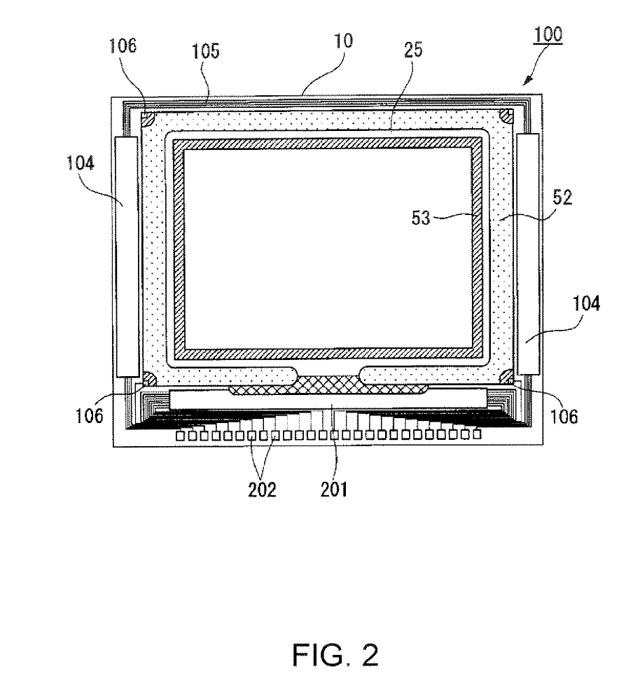

FIG. 2 is a plan view of the liquid crystal display device 100 showing its overall structure. The liquid crystal display device 100 includes a TFT array substrate 10 and an opposing substrate 25 which are adhered together through a sealing member 52 that has a substantially rectangular frame shape when it is viewed in plan. The liquid crystal held between the substrates 10 and 25 is enclosed in the substrates by the sealing member 52. As shown in FIG. 2, the peripheral of the opposing substrate 25 is lined with the peripheral of the sealing member 52 when they are viewed in plan.

In a region inside the sealing member 52, a light shielding film (peripheral partition) 53 made of a light shielding material is formed in a rectangular frame shape. In a peripheral circuit region outside the sealing member 52, a data line driving circuit 201 and mounting terminals 202 are formed along one side of the TFT array substrate 10, and scan line driving circuits 104, 104 are formed along the two sides adjacent to that side of the TFT array substrate. On the remaining one side of the TFT array substrate 10, a plurality of wirings 105 are provided for coupling the scanning line driving circuits 104. A plurality of intra-substrate conductive members 106 which electrically couple the TFT array substrate 10 and the opposing substrate 25 is provided at the corners of the opposing substrate 25.

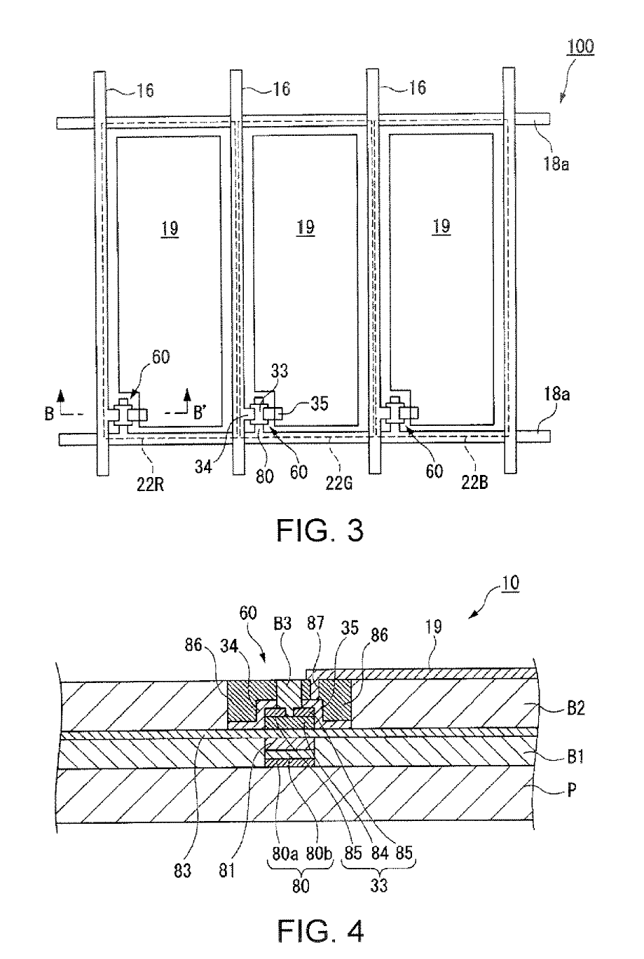

FIG. 3 is a plan diagram for schematically showing a pixel structure of the liquid crystal display device 100. A plurality of the scan lines 18a extends in one direction and a plurality of the data lines 16 extends in the direction orthogonal to the scan lines 18a in the display region of the liquid crystal display device 100. An area surrounded by two scan lines 18a and two data lines 16, which has a rectangular shape as viewed in plan, is a dot region as shown in FIG. 3. A color filter of one of the three primary colors is formed in each dot region. Three dot regions shown in the figure form a one pixel area which has three colored areas 22R, 22G, 22B. These colored areas 22R, 22G, 22B are repeatedly arranged in the display region of the liquid crystal display device 100.

In each dot region shown in FIG. 3, the pixel electrode 19 that is made of a light transmissive conductive film such as indium tin oxide (ITO) and has a rectangular shape as viewed in plan is provided. Furthermore, the TFT 60 is provided among the pixel electrode 19, the scan line 18a and the data line 16. The TFT 60 includes a semiconductor layer 33, a gate electrode 80 provided under (the side close to the substrate) the semiconductor layer 33, a source electrode 34 provided above the semiconductor layer 33, and a drain electrode 35. A channel region of the TFT 60 is formed in the region between the semiconductor layer 33 and the gate electrode 80. A source region and a drain region are respectively formed in semiconductor regions on the both sides of the channel region.

The gate electrode 80 is formed by ramifying a part of the scan line 18a in the direction where the data line 16 extends and its tip opposes the semiconductor layer 33 in the vertical direction of the page with an unshown insulating film (gate insulating film) interposed therebetween. The source electrode 34 is formed by ramifying a part of the data line 16 in the direction where the scan line 18a extends. The source electrode 34 is electrically coupled to the semiconductor layer 33 (the source region). One end (the left end in the figure) of the drain electrode 35 is electrically coupled to the semiconductor layer 33 (the drain region) and the other end (the right end in the figure) of the drain electrode 35 is electrically coupled to the pixel electrode 19.

Such TFT 60 serves as a switching element for writing the image signal supplied through the data line 16 into the liquid crystal at a prescribed timing when it is turned on by an inputted gate signal from the scan line 18a.

FIG. 4 is a sectional view of the TFT array substrate 10 along the line B-B′ in FIG. 3 showing it main feature. The TFT array substrate 10 is a glass substrate (substrate) P whose inner side (the upper side in the figure) has the TFT 60 and the pixel electrode 19 according to the invention as shown in FIG. 4. A first bank B1 that has an opening is formed on the glass substrate P. The gate electrode 80 and a part of a gate insulating film 83 that covers the gate electrode 80 are formed so as to fill the opening of the bank B1.

The gate electrode 80 includes a first electrode layer (first pattern) 80a that serves as an adhesion layer, a second electrode layer (second pattern) 80b that serves as a main conductive layer and a cap layer 81, and these layers are laid over one another in this order on the glass substrate P. The first electrode layer 80a is made of a metal material such as Mn, Ti and W. The second electrode layer 80b is made of a metal material such as Ag, Cu and Al. The cap layer 81 is made of a metal material such as Ni and TiN.

A second bank B2 is formed above the first bank B1 with the gate insulating film 83 made of SiNx interposed therebetween. The second bank B2 has an opening for exposing an area which includes the gate electrode 80. The semiconductor layer 33 is formed in the opening where corresponds to the gate electrode 80 in plan with the gate insulating film 83 interposed therebetween. The semiconductor layer 33 includes an amorphous silicon layer 84 and an N⁺ silicon layer 85 formed on the amorphous silicon layer 84. The N⁺ silicon layer 85 is divided into two parts with a certain space therebetween on the amorphous silicon layer 84. One part of the N⁺ silicon layer 85 is electrically coupled to the source electrode 34 that is formed on the both of the gate insulating film 83 and the N⁺ silicon layer 85. The other part of the N⁺ silicon layer 85 is electrically coupled to the drain electrode 35 that is formed on the both of the gate insulating film 83 and the N⁺ silicon layer 85. The amorphous silicon layer 84 and the N⁺ silicon layer 85 that are for ohmic contact can be made by inkjet printing a liquid material containing a silicon compound and a dorpant, A specific example of the silicon compound is a high-order silane produced by photo-polymerizing silane having more than one cyclic structure such as cyclopentasilane with ultraviolet irradiation. As a specific example of the dorpant, a material containing an element in the group III such as phosphorus or the group V such as boron of the periodic table can be named.

The source electrode 34 and the drain electrode 35 are separated each other by a second bank B3 formed in the opening of the second bank B2, and are formed in the areas defined by the second banks B2, B3 by a hereinafter described droplet discharge method. Furthermore, an insulating material 86 is provided on the source electrode 34 and the drain electrode 35 so as to fill the opening. A contact hole 87 is formed in the insulating material 86. The pixel electrode 19 formed on the second bank B2 and the insulating material 86 is electrically coupled to the drain electrode 35 through the contact hole 87. In the above-described manner, the TFT 60 of the invention is formed.

As shown in FIG. 3, the data line 16, the source electrode 34, the scan line 18a and the gate electrode 80 are formed so as to be integrated so that the data line 16 is also covered with the insulating material 86 in the same way as the source electrode 34 and the scan line 18a is covered with the cap layer 81 in the same way as the gate electrode 80.

In an actual product, an alignment film which controls an initial orientation state of the liquid crystal is formed on the surface of the pixel electrode 19, the second banks B2, B3 and the insulating material 86. Furthermore, a retardation plate and a deflection plate that control a polarization state of the light beam entering the liquid crystal layer are provided on the outer side of the glass substrate P. Where the liquid crystal display device is a transmissive type or a trans-reflective type, a backlight which is an illuminating means is provided on the outside of the TFT array substrate 10 (back side of a panel).

Though the opposing substrate 25 will not be illustrated in detail, the opposing substrate 25 has a color filter layer in which the colored areas 22R, 22G, 22B as shown in FIG. 3 are arranged and an opposing electrode made of a Rat light-transmissive conductive film. The color filter layer and the opposing electrode are formed in layers on the inner side of the substrate which is the similar one as the glass substrate P. An alignment film which is same as the one on the TFT array substrate is formed on the opposing electrode. A retardation plate and a deflection plate may be provided on the outer side of the substrate if needed.

The liquid crystal layer enclosed between the TFT array substrate 10 and the opposing substrate 25 is mainly composed of liquid crystal molecules. Any type of liquid crystal molecules such as a nematic liquid crystal and a smectic liquid crystal can be used for the liquid crystal layer as long as it can be oriented. However, in case of a TN type liquid crystal panel, ones forming the nematic liquid crystal are preferably used. As such liquid crystals, for example, there are a phenylcyclohexane derivative liquid crystal, a biphenyl derivative liquid crystal, a biphenylcyclohexane derivative liquid crystal, a terphenyl derivative liquid crystal, a phenylether derivative liquid crystal, a phenylester derivative liquid crystal, a bicyclohexane derivative liquid crystal, an azomethine derivative liquid crystal, an azoxy derivative liquid crystal, a pyrimidine derivative liquid crystal, a dioxane derivative liquid crystal, a cubane derivative liquid crystal and the like.

The liquid crystal display device 100 of the embodiment of the invention having the above-described structure can display any tone image by modulating the light entered from the back light through the liquid crystal layer whose orientation is controlled by the applied voltage. Furthermore, since the colored areas 22R, 22G, 22B are provided in each dot, the liquid crystal display device 100 can display any colored image by mixing light beams colored in the three primary colors (R, G, B) by each pixel.

Method of Manufacturing Thin Film Transistor

Next, an embodiment of a pattern formation method of the invention is described based on a manufacturing method of the above described TFT 60. The gate electrode 80, the source electrode 34 and the drain electrode 35 of the TFT 60 are formed by patterning using the droplet discharge method. The pixel electrode 19 is also formed by the droplet discharge method.

Droplet Discharge Device

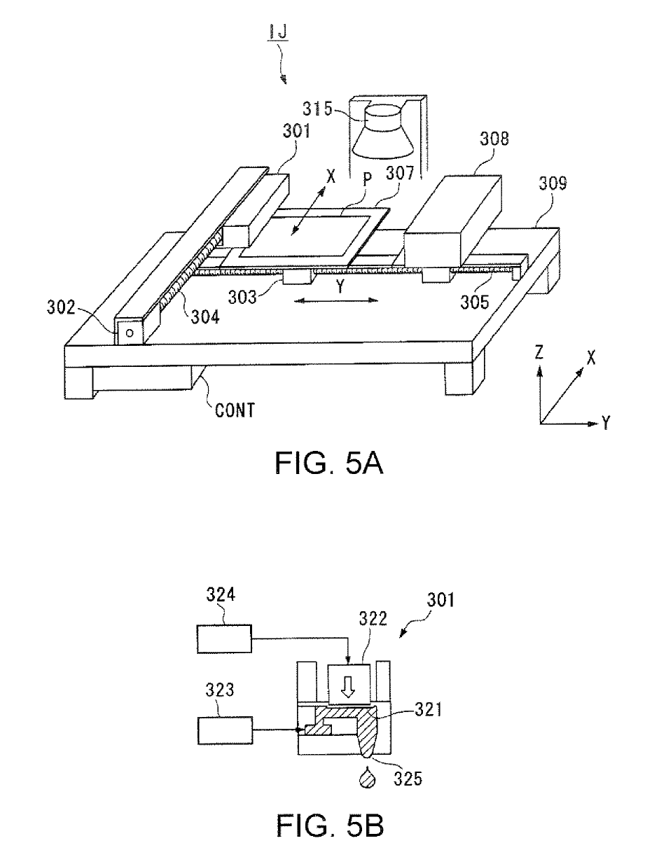

Firstly, a droplet discharge device used in the manufacturing method of the embodiment of the invention is described. According to the manufacturing method of the embodiment, ink (a functional liquid) containing conductive particles and other functional material is discharged in a droplet form from a nozzle of a droplet discharge head provided in the droplet discharge device so as to form elements composing the thin film transistor. The droplet discharge device having the structure shown in FIG. 5 can be used in the manufacturing method according to the embodiment.

FIG. 5A is a schematic perspective view showing a structure of a droplet discharge device IJ used in the embodiment.

The droplet discharge device IJ has a droplet discharge head 301, an X-way drive axis 304, a Y-way guide axis 305, a controller CONT, a stage 307, a cleaning mechanical section 308, a table 309 and a heater 315.

The stage 307 surmounts the substrate P to which the ink (functional liquid) is provided by the droplet discharge device IJ. The stage 307 has an unshown feature to fix the substrate P in a reference position.

The droplet discharge head 301 is a multi-nozzle type head equipped with a plurality of discharge nozzles. A Y-axis direction corresponds to the longitudinal direction of the droplet discharge head 301. A discharge nozzle is provided in the plural number on a lower face of the droplet discharge head 301. The nozzles align in the Y-axis direction and are provided with a regular space therebetween. From the nozzle of the droplet discharge head 301, the above-mentioned ink (functional liquid) is discharged to the substrate P that is held by the stage 307.

An X-way driving motor 302 is coupled to the X-way drive axis 304. The X-way driving motor 302 is a stepping motor and the like, and rotates the X-way drive axis 304 when an X-way driving signal is provided from the controller CONT. When the X-way drive axis 304 is rotated, the droplet discharge head 301 moves in an X-axis direction.

The Y-way guide axis 305 is fixed in such a way that its position will not move relative to the table 309. The stage 307 has a Y-way driving motor 303. The Y-way driving motor 303 is a stepping motor and the like. When a Y-way driving signal is provided from the controller CONT, the Y-way driving motor 303 moves the stage 307 in the Y-axis direction.

The controller CONT supplies a voltage that controls the discharge of droplets to the droplet discharge head 301. The controller CONT also supplies a drive pulse signal for controlling an X-axis direction movement of the droplet discharge head 301 to the X-way driving motor 302. The controller CONT also supplies a drive pulse signal for controlling a Y-axis direction movement of the stage 307 to the Y-way driving motor 303.

The cleaning mechanical section 308 cleans the droplet discharge head 301. The cleaning mechanical section 308 has an unshown Y-directional driving motor. The cleaning mechanical section 308 is driven by the driving motor and moves along with the Y-way guide axis 305. This movement of the cleaning mechanical section 308 is also controlled by the controller CONT.

The heater 315 is used to perform a heat treatment of the substrate P by lamp annealing. Solvent contained in the liquid material that is applied to the substrate P will be evaporated and dried with the heater 315. Power on and off of this heater 315 is also controlled by the controller CONT.

The droplet discharge device IJ discharges a droplet to the substrate P as relatively moving the droplet discharge head 301 and the stage 307 that supports the substrate P. In the following description, the X-axis direction is the scan direction and the Y-axis direction which is orthogonal to the X-axis direction is a non-scan direction. Accordingly, the discharge nozzles of the droplet discharge head 301 align in the Y-axis direction or the non-scan direction and are provided with a regular space therebetween. Though the droplet discharge head 301 is placed orthogonal to the traveling direction of the substrate P as shown in FIG. 5A, the installed angle of the droplet discharge head 301 can be adjusted so as to cross the traveling direction of the substrate P. By adjusting the angle of the droplet discharge head 301, it is possible to control the pitch between the nozzles. Furthermore, the distance between the substrate P and the nozzle face may be made freely adjustable.

FIG. 5B is a schematic diagram of the droplet discharge head for explaining the discharge mechanism of ink by a piezo method.

In FIG. 5B, a piezo element 322 is provided adjacent to a liquid room 321 in which the ink (functional liquid) is kept. The ink is supplied to the liquid room 321 through a liquid material supply system 323 including a material tank that stores the ink. The piezo element 322 is coupled to a driving circuit 324. Voltage is applied to the piezo element 322 through the driving circuit 324 and the piezo element 322 is deformed. The liquid room 321 is elastically deformed by the deformation of the piezo element 322. Accordingly, the liquid material is discharged from a nozzle 325 due to the variation in the capacity of the liquid room at the time of the elastic deformation.

In this case, a degree of distortion of the piezo element 322 can be controlled by changing a value of the applied voltage. A distortion speed of the piezo element 322 can be controlled by changing a frequency of the applied voltage.

In the droplet discharge by the piezo method, the material will not be heated so that it has an advantage that composition of the material is hardly affected.

Ink (Functional Liquid)

Here, the ink (functional liquid) used for forming conductive patterns of the gate electrode 80, the source electrode 34 and the drain electrode 35 in the manufacturing method of the embodiment will be described.

The ink for the conductive pattern used in this embodiment is a dispersion liquid in which conductive particles are dispersed in a dispersion medium or a solution of its precursor. As the conductive particles, for example, metal particles which contain gold, silver, copper, palladium, niobium or nickel, precursors, alloys and oxides of these metal particles, a conductive polymer, particles of indium tin oxide (ITO) and the like can be used. To increase the dispersibility of these conductive particles, the surface of each particle may be coated with an organic material. The diameter of the conductive particle is preferably about 1 nm-0.1 um. When it is larger than 0.1 μm, not only there is a concern of clogging at the nozzle of the liquid discharge head 301, but also the density of the obtained film could be deteriorated. When it is smaller than 1 nm, the volume ratio of the coating material to the particle becomes large and the ratio of the organic matter which can be obtained in the film could become excessive.

The dispersion medium is not particularly limited as long as it can disperse the above-mentioned conductive particles therein without condensation. For example, the examples include, in addition to water; alcohol such as methanol, ethanol, propanol and butanol; hydrocarbon compounds such as n-heptane, n-octane, decane, dodecane, tetradecane, toluene, xylene, cymene, dulene, indent, dipentene, tetrahydronaphthalene, decahydronaphthalene and cyclohexylbenzene; ether compounds such as ethyleneglycoldimethyl ether, ethyleneglycoldiethvl ether, ethyleneglycolmethylethyl ether, diethyleneglycoldimethyl ether, diethylenglycoldiethyl ether, diethyleneglycolmethylethyl ether, 1,2-dirnethoxyethane, bis (2-methoxyethyl)ether, and p-dioxane; and polar compounds such as propylene carbonate, [gamma]-butyrolactone, N-methyl-2-pyrolidone, dimethylformamide, dimethylsulfoxide and cyclohexanone. Among these, water, alcohols, hydrocarbon compounds and ether compounds are preferable in terms of the dispersibility of the particles, stability of the dispersion liquid, and easy application to the droplet discharge method (inkjet method). Water and hydrocarbon compounds are especially preferable as the dispersion medium.

It is preferable that the surface tension of the dispersion liquid of the above-mentioned conductive particles is in the range of 0.02 N/m to 0.07 N/m. This is because when liquid is discharged by the droplet discharge method, if the surface tension is less than 0.02 N/m, the wettability of the ink composition with respect to the nozzle surface increases so that the discharge direction tends to deviate. If the surface tension exceeds 0.07 N/m, the shape of the meniscus at the tip of the nozzle becomes unstable, making it difficult to control the discharge amount and the discharge timing. A good way to adjust the surface tension is to add a small amount of a fluorine based, silicon based or nonionic based surface tension modifier to the above-mentioned dispersion liquid to an extent not to largely decrease the contact angle with the substrate. The nonionic surface tension modifier increases the wettability of the liquid on the substrate, improves the leveling property of the film, and helps to prevent the occurrence of minute ruggedness on the film. The above-mentioned surface tension modifier may contain organic compounds such as alcohol, ether, ester, ketone, and the like according to need.

The viscosity of the above-mentioned dispersion liquid is preferably above 1 mPa·s and below 50 mPa·s. This is because when liquid material is discharged in the droplet form by the droplet discharge method, if the viscosity is smaller than 1 mPa·s, the area around the nozzle is easily contaminated by the leakage of the ink. If the viscosity is higher than 50 mPa·s, the frequency of clogging occurring at the nozzle hole increases, this not only makes it difficult to smoothly discharge droplets but also decrease the amount of the droplet discharged from the nozzle.

For example, a polysilazane solution can be used for forming the first bank B1 and the second bank B2. This polysilazane solution is mainly composed of a solid polysilazane. As such polysilazane solution, a photosensitive polysilazane solution containing the polysilazane and a photo-oxidation product can be employed This photosensitive polysilazane solution serves as a positive resist and it can be directly patterned by exposure and processing. As such photosensitive polysilazane, for example, the polysilazane disclosed in JP-A-2002-72504 can be named. An example of the photo-oxidation product contained in the polysilazane is also disclosed in JP-A-2002-72504.

In a case that the polysilazane is a polymethylsilazane presented by chemical formula (1) written below, a part of the polymethylsilazane is hydrolyzed by a hydration treatment which is described later as shown in chemical formula (2) and chemical formula (3). By further conducting a heat treatment lower than 350° C., it is condensed as shown in chemical formulas (4) through (6) and turns into polymethylsiloxane [—(SiCH₃O_{1.5})n—]. If a heat treatment higher than 350° C. is carried out, desorption of a side-chain methyl group occurs. Especially, the heat treatment higher of 400-450° C. desorbs almost all the side-chain methyl groups and the polymethylsilazane turns into polysiloxane, though its chemical reaction is not shown as the chemical formulae here. It is note that chemical formulas (2) through (6) are simplified and only basic constituent units (repeat units) in the chemical compounds are shown in order to simply explain the reaction mechanism.

The polymethylsiloxane or the polysiloxane produced in the above-described way has the polysiloxane skeleton which is inorganic so that a film of these compounds becomes sufficiently dense. Accordingly, the surface of the layer (film) becomes appropriately flat and even. In addition, it has a high heat resistance, and this film is appropriate for the bank material.

Chemical Formulae

(1) —(SiCH₃(NH)_{1.5})n—

(2) SiCH₃(NH)_{1.5}+H₂O→SiCH₃(NH)(OH)+0.5NH₃

(3) SiCH₃(NH)_{1.5}+2H₂O→SiCH₃(NH)_{0.5}(OH)₂+NH₃

(4) SiCH₃(NH) (OH)+SiCH₃(NH) (OH)+H₂O→2SiCH₃O_{1.5}+2NH₃

(5) SiCH₃(NH) (OH)+SiCH₃(NH)_{0.5}(OH)₂→2SiCH₃O_{1.5}+1.5NH₃

(6) SiCH₃(NH)_{0.5}(OH)₂+SiCH₃(NH)_{0.5}(OH)₂→2SiCH₃O_{1.5}+NH₃+H₂O

A Manufacturing Method of TFT Array Substrate

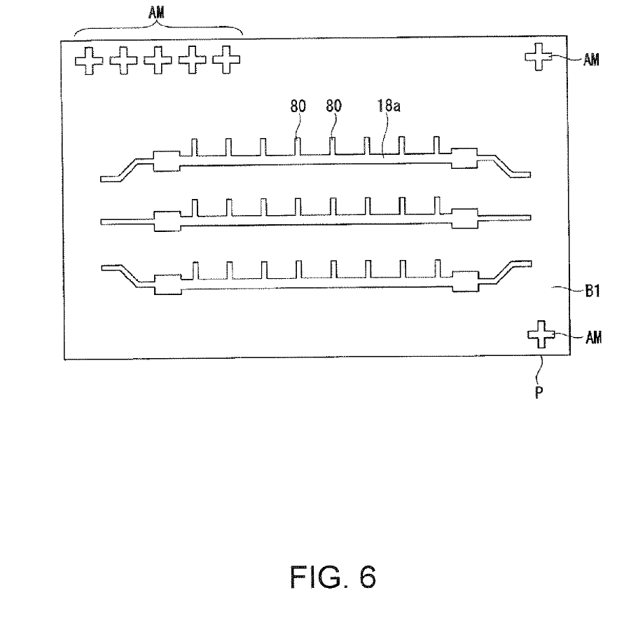

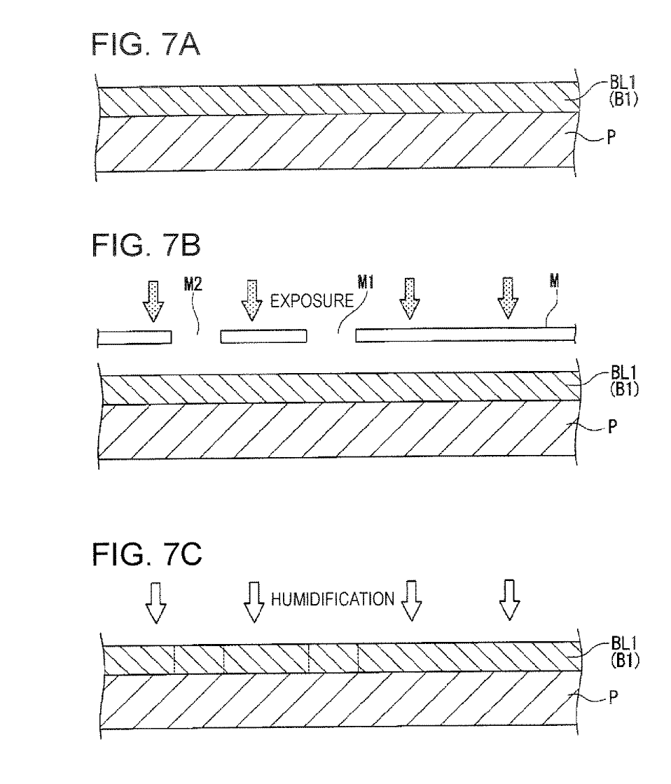

Processes of manufacturing method of the TFT array 10 including the method of manufacturing the TFT 60 is hereinafter described with reference to FIGS. 6 through 11. FIGS. 7A through 11C are a series of sectional views showing processes in the manufacturing method of the invention.

Gate Electrode Forming Process

In this process, the gate electrode 80 (and the scan line 18a) and a plurality of cross-shape alignment marks AM (seven of them in FIG. 6) are formed on the substrate P. The alignment marks AM are used in the processes of forming the gate electrode 80 and the TFT 60.

The alignment marks AM are usually provided in three positions (upper left, upper right and lower right in FIG. 6) in order to carry out alignment in the direction where the scan line 18a extends (a X direction), in a Y direction orthogonal to this direction with respect to the substrate P, and in an axial direction (a Z direction) perpendicular to the face of the substrate P. Here, more than one alignment mark is formed in each place (though only the alignment marks positioned at the upper left are shown in the plural number in FIG. 6) because these alignment marks are used at the time when the second electrode layer 80b and the semiconductor layer 33 are formed.

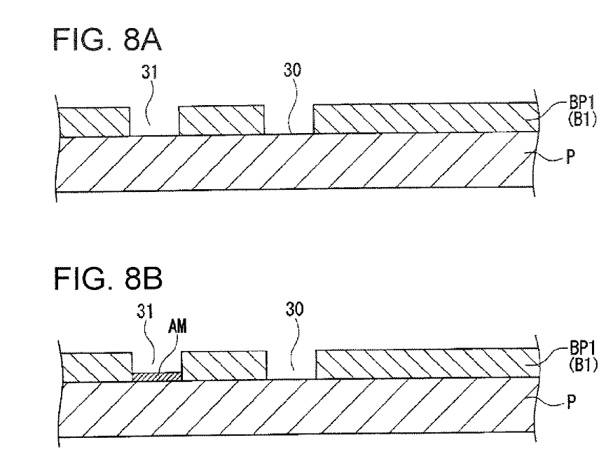

The glass substrate P made of non-alkali glass and the like is provided. And the first bank B1 is firstly formed on one face of the substrate as shown FIG. 7. The gate electrode 80 is formed in an opening 30 by dropping a prescribed ink (the functional liquid) into the opening 30 formed in the first bank B1 as shown in FIG. 8. This gate electrode forming process includes a bank formation process, a hydrophobicity imparting process, a first electrode layer formation process, a second electrode layer formation process and a baking process.

First Bank Formation Process

Firstly, in order to form the gate electrode 80 (and the scan line 18a) having a designated pattern on the glass substrate, the first bank having the opening in a predetermined pattern is formed on the glass substrate P. This first bank is a partition member that comparts the substrate face in plan. A photolithography method is especially preferable for forming the bank. Specifically describing, the above-mentioned photosensitive polysilazane solution is applied according to the height of the bank formed on the glass substrate P by spin coating, spray coating, roll coating, dye coating, dip coating or the like as shown in FIG. 7A, forming a polysilazane thin film BL1.

Subsequently, the obtained polysilazane thin film BL1 is pre-baked by for example a hotplate at 110° C. for about one minute.

The polysilazane thin film BL1 is then exposed by using a mask M as shown in FIG. 7B. This mask M has an opening M1 and an opening M2. The opening M1 is formed at the position and has the shape corresponding to the gate electrode 80 (and the scan line 18a). The opening M2 is formed at the position and has the shape corresponding to the alignment mark AM.

Since the polysilazane thin film BL1 serves as the positive resist at this point as described above, the areas where should be removed in a later performed developing process are selectively exposed. A light source used in this exposure process is adequately selected in consideration of the photosensitivity and the composition of the photosensitive polysilazane solution. Such light source can be selected from the ones used in a common exposure of photoresist such as a high-pressure mercury lamp, a low-pressure mercury lamp, a metal halide lamp, a xenon lamp, an excimer laser, X-rays, electron rays and the like. The amount of energy of the irradiation depends on the employed light source and the film thickness, though it is preferably set to be 0.05 mJ/cm² or more, more preferably 0.1 mJ/cm² or more. There is no specific upper limit however it is not practical to set a large amount of irradiation energy in terms of processing time. Therefore, it is usually set to smaller than 10,000 mJ/cm². The exposure is usually performed in an ambient atmosphere (the air) or in a nitrogen atmosphere. In stead of these, an oxygen-enriched atmosphere may be used in order to promote decomposition of the polysilazane.

After the above-described exposure process is performed to the photosensitive polysilazane thin film BL1 which contains the photo-oxidation product, acid is selectively generated in the film especially where was exposed and this cleaves a Si—N bond in the polysilazane. It then reacts with water in the atmosphere and the polysilazane thin film BL1 is partially hydrolyzed as shown in the above chemical formula (2) or chemical formula (3). Eventually, a silanol (Si—OH) bond is formed and the polysilazane is decomposed.

Next, in order to further promote the generation of such silanol (Si—OH) bond and the decomposition of the polysilazane, a humidification treatment under a condition of for example 25° C. and 85% relative humidity is performed for about five minutes to the polysilazane thin film BL1 after the exposure as shown in FIG. 7C, When water is continuously supplied into the polysilazane thin film BL1 in this way, the acid which contributed to the cleavage of the Si—N bond in the polysilazane repeatedly works as the cleavage catalyst This Si—OH bond is also generated in the exposure process. However, the humidification treatment after the exposure of the film further promotes the generation of the Si—OH bonds in the polysilazane.

The higher the humidity in the atmosphere of the humidification treatment is, the faster the speed of the Si—OH generation can be. However, when the humidity is too high, dew condensation could occur on the surface of the film. In this respect, the relative humidity is practically set to 90% or less. Such humidification treatment can be carried out by contacting the polysilazane thin film BL1 with the air containing moisture. More specifically, the substrate P after the exposure is placed in humidification treatment equipment and the moisture containing air is successively introduced into the humidification treatment equipment, Alternatively, the substrate P after the exposure is placed in the humidification treatment equipment in which the moisture containing air is already introduced and adjusted to an adequate humidity, and then the substrate is left in the equipment for a certain time period.

Next, the polysilazane thin film BL1 after the humidification treatment is developed with for example 2.38% tetramethylammoniumhydroxide (TMAH) solution at 25° C., and the unexposed part is selectively removed. In this way, a first bank precursor BP1 having the opening 30 that corresponds to the forming region of the gate electrode 80 and an opening 31 that corresponds to the forming region of the alignment mark AM is formed in this one process. The first bank precursor BP1 serves as a marking partition wall at the time when the gate electrode 80 and the alignment mark AM are formed. In addition to TMAH, alkaline developers such as choline, sodium silicate, sodium hydroxide and potassium hydroxide can be used.

Hydrophobicity Imparting Process

Next, after the precursor is rinsed with deionized water if required, a hydrophobicity imparting process is performed so as to impart the hydrophobicity to the surface of the first bank precursor BP1. As a method of imparting the hydrophobicity, for example, a plasma treatment (CF₄ plasma treatment) using tetrafluoromethane as a treatment gas in an atmosphere can be adopted. Conditions of the CF₄ plasma treatment in this embodiment are set, for example, as follows; 50-1000 kW of plasma power, 50-100 ml/min of a tetrafluoromethane gas flow rate, 0.5-1020 mm/sec of a substrate transport speed relative to a plasma discharge electrode, and 70-90° C. of the substrate temperature. As the treatment gas, in addition to tetrafluoromethane, other fluorocarbon based gases can be used.

By performing such hydrophobic treatment, a fluorine group is introduced into the alkyl group composing the first bank precursor BP1 and a high hydrophobicity is imparted to the first bank precursor BP1.

It is preferable that an ashing treatment using O₂ plasma or an ultraviolet (UV) irradiation treatment is performed prior to the above-mentioned hydrophobicity imparting process in order to clean the surface of the substrate P which is exposed on the bottom of the openings 30, 31. With this treatment, remaining of the bank material on the surface of the substrate P can be removed and it is possible to increase a difference in the contact angle between the first bank precursor BP1 and the substrate surface after the hydrophobic treatment. Consequently, droplets which are provided on the openings 30, 31 in a later process can be accurately enclosed inside the openings 30, 31.

The above-mentioned O₂ ashing treatment can be performed by irradiating the substrate P with oxygen plasma discharged from the plasma discharge electrode. Conditions of the O₂ ashing treatment are set for example as follows: 50-1000 W of the plasma power, 50-100 ml/min of an oxygen gas flow rate, 0.510-10 mm/sec of the substrate transport speed relative to the plasma discharge electrode, and 70-90° C. of the substrate temperature.

The hydrophobicity imparting process (the CF₄ plasma treatment) of the first bank precursor BP1 has a little affect on the surface of the substrate P where hydrophilicity is given by the above-mentioned remaining removal treatment. However, especially in the case of the glass substrate, the fluorine group is not so much introduced in to the substrate P by the hydrophobicity imparting process. Therefore, the hydrophilicity or wettability of the substrate P will not be lost in a practical sense.

First Electrode Layer Formation Process

Next, a first electrode layer forming ink (not shown in the figure) and an alignment mark forming ink which is the same material as that of the first electrode layer forming ink are discharged from the liquid discharge head 301 of the droplet discharge device IJ onto the opening 31. Here, the ink containing the conductive particles made of manganese (Mn) and a tetradecane solvent (dispersion medium) is discharged. At this point, the hydrophobicity is imparted to the surface of the first bank B1 and the hydrophilicity is given to the substrate surface in the bottom of the opening 31. Accordingly, even if a part of the discharged droplets is placed on the first bank B1, the bank surface respells the droplets and they slip into the opening 31.

After the droplets of the alignment mark forming ink are discharged, a drying process is performed in order to remove the dispersion medium if required. The drying process can be performed by a commonly used heating means to heat the substrate P, for example, a hot plate and an electric furnace. In this embodiment, for example, heating of 180° C. for about 60 minutes is carried out. This heating is not necessarily performed in the air but can be performed in a nitrogen gas atmosphere and the like.

This drying process can also be performed by lamp annealing. Light source of the lamp annealing is not particularly limited, though an infrared lamp, a xenon lamp, a YAG laser, an argon laser, a carbon dioxide gas laser, and excimer lasers such as XeF, XeCl, XeBr, KrF, KrCl, ArF and ArCl can be used as the light source. These light sources are generally used in an output range of above 10 W and below 5000 W. However one in a-range of above 100 W and below 1000 W is sufficient for this embodiment. By performing this intermediate drying process, the solid alignment mark AM is formed in the opening 31 as shown in FIG. 8B.

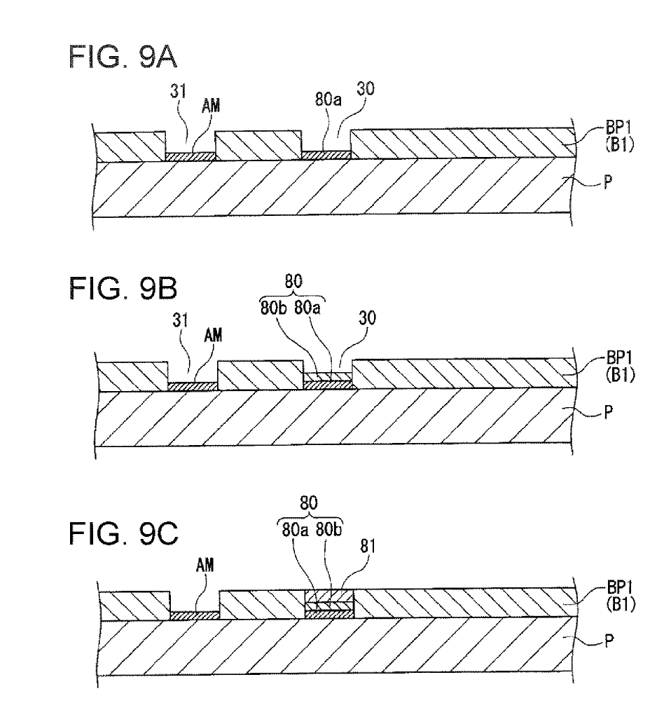

Next, the alignment mark AM formed in the previous process is imaged by an unshown CCD camera and the like, and the droplet discharge head 301 is aligned with the substrate P with reference to the result of the imaging. After that, the ink droplets made of the same material as that of the alignment mark AM are discharged into the opening 30 and then the above-described drying process is performed. In this way, the solid first electrode layer 80a is formed in the opening 30 as shown in FIG. 9A.

Second Electrode Layer Formation Process

Next, a second electrode layer forming ink (not shown in the figure) is discharged by the droplet discharge method using the droplet discharge device and the ink is placed in the opening 30 of the first bank precursor BP1. At this point, the alignment mark AM formed in the previous process is also imaged by the unshown CCD camera and the like, and the droplet discharge head 301 is aligned with the substrate P with reference to the result of the imaging.

Here, the ink containing the conductive particles made of silver (Ag) and a diethylene glycol diethylether solvent (dispersion medium) is discharged. At this point, the hydrophobicity is already imparted to the surface of the first bank precursor BP1 and the hydrophilicity is given to the substrate surface in the bottom of the opening 30. Accordingly, even if a part of the discharged droplets is placed on the precursor BP1, the bank surface respells the droplet and it slips into the opening 30. It is note that the surface of the first electrode layer 80a which is formed in the opening 30 ahead does not always have a high affinity for the ink that is discharged in this process. In that case, an interlayer that improves the wettability of the ink may be formed on the first electrode layer 80a prior to the ink discharge. A material for the interlayer is selected according to the type of the dispersion medium of the ink. Where the ink uses aqueous dispersion medium like this embodiment, an interlayer made of for example titanium oxide is formed so as to obtain a fine wettability at the surface of the interlayer.

After the droplets are discharged, the same drying process as the above-described one is preformed in order to remove the dispersion medium if required. The drying process can be performed by a commonly used heating means to heat the substrate P, for example, a hot plate and an electric furnace. In this embodiment, the heating conditions are for example 180° C. for about 60 minutes. This heating is not necessarily performed in the air but can be performed in the nitrogen gas atmosphere and the like.

This drying process can also be performed by the lamp annealing. As the light source of the lamp annealing, the above-mentioned ones used in the intermediate drying process after the first electrode layer formation process can be used. The power of the heating can also be in the range of above 100 W and below 1000 W, By carrying out this intermediate drying process, the solid second electrode layer 80b is formed on the first electrode layer 80a as shown in FIG. 9B.

After that, in the same manner as the first electrode layer 80a and the second electrode layer 8Db, an ink containing conductive particles of Ni and the like dispersed in an organic dispersion medium is discharged into the opening 30 and the drying process is subsequently performed. In this way, the cap layer 81 is formed on the second electrode layer 80b as shown in FIG. 9C.

Baking Process

The dispersion medium should be completely removed from the dried film after the discharged process in order to improve the electric contact among conductive particles. In case that the surface of the conductive particle is coated with an organic coating agent and the like in order to improve the dispersibility in the solution, this coating should be removed. For this purpose, the substrate after the discharge process is treated with heat and/or light.

This heat treatment and/or the light treatment are normally performed in the air. However, it may be performed in an inert gas atmosphere such as hydrogen, nitrogen, argon and helium. The temperature of the heat treatment and/or the light treatment is determined considering the boiling point (vapor pressure) of the dispersion medium, the type and the pressure of the atmosphere gas, the thermal behavior such as the dispersibility or the oxidizing property of the particles, the presence/absence of the coating, and the heat resistant temperature of the substrate. In this embodiment, the first electrode layer 80a, the second electrode layer 80b and the cap layer 81 are made of the above-mentioned materials so that the baking temperature is set to less than 300° C.

By conducting the above-described processes, the dried film after the discharge process turns into the conductive film in which the electric contact is secured among the particles, and the gate electrode 80 having the layered structure composed of the first electrode layer 80a, the second electrode layer 80b and the cap layer 81 is formed as shown in FIG. 9C. The scan line 18a integrated with the gate electrode 80 is also formed on the glass substrate P through the above-described processes as shown in FIG. 3.

Semiconductor Layer Formation Process

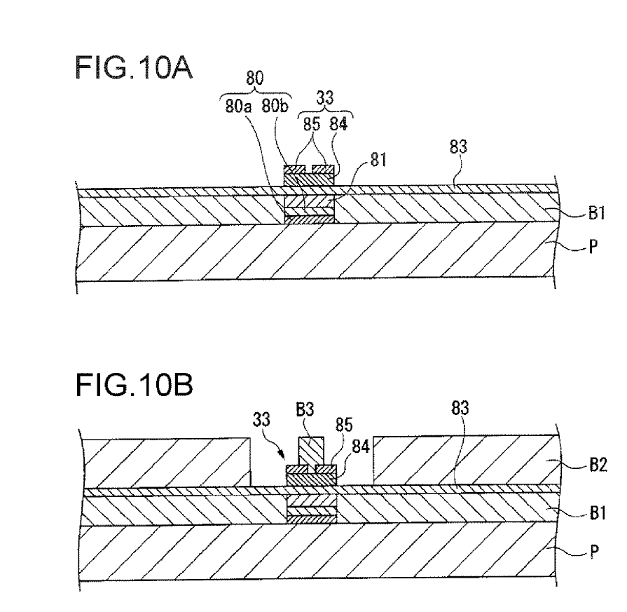

Next, as shown in FIG. 10A, the gate insulating film 83 made of SiNx and the semiconductor layer 33 including the amorphous silicon layer 84 and the N⁺ silicon layer 85 are formed by a plasma chemical vapor deposition (CVD) method in which material gases and the plasma conditions are adequately selected. The amorphous silicon layer 84 and the N⁺ silicon layer 85 are formed by depositing an amorphous silicon film and a N⁺ silicon film by the CVD method and then patterning them into a prescribed pattern by a photolithography method. This patterning is performed by selectively providing a resist having a substantially concave shape which is similar to the side cross-sectional configuration of the semiconductor layer 33 shown in the figure on the surface of the N⁺ silicon film, and then conducting an etching using this resist as a mask. By this patterning, the area of the N⁺ silicon layer 85 where overlaps the gate electrode 80 in plan is selectively removed to be divided into two regions, These N⁺ silicon layers 85, 85 are respectively turned into a source contact region and a drain contact region.

In a bank formation process in the second layer following the semiconductor layer formation process, the second bank B2 is formed on the gate insulating film 83 as shown in FIG. 10B. At the same time, the second bank B3 is formed over the area between the divided N⁺ silicon layers 85, 85 by patterning by the photolithography method. The second bank B3 electrically isolates between the N⁺ silicon layers 85, 85.

When the patterning by the photolithography method is performed in the above-described semiconductor layer formation process and the second layer bank formation process, the mask is aligned with the substrate P by measuring the above-mentioned alignment mark AM.

The CCD camera imaging the alignment mark AM preferably has a light source which has a high transparency with the gate insulating film 83 made of SiNx, the amorphous silicon film and the N⁺ silicon film and has a low transparency with the alignment mark AM (Mn) so that it becomes easier to recognize the alignment mark AM. Since this alignment mark AM is further used in a later process, it is preferable that the amorphous silicon film and the N⁺ silicon film be removed from the alignment mark AM formed area at the time of the patterning of the amorphous silicon film and the N⁺ silicon film.

Electrode Formation Process

Next, the source electrode 34 and the drain electrode 35 shown in FIG. 4 is formed on the glass substrate P on which the semiconductor layer 33.

Hydrophobicity Imparting Process

The hydrophobicity imparting process is performed so as to impart the hydrophobicity to the surface to the second banks B2, B3. As the method of imparting the hydrophobicity, for example, the plasma treatment (CF₄ plasma treatment) using tetrafluoromethane as the treatment gas in an atmosphere can be adopted.

Electrode Film Formation Process

Next, the ink (functional liquid) for forming the source electrode 34 and the drain electrode 35 shown in FIG. 4 is discharged into the area surrounded by the second bank parts B2, B3 by the above-mentioned droplet discharge device IJ. Before conducting the discharge, the droplet discharge device IJ is aligned with the substrate P by using the above-mentioned alignment mark AM. Here, the ink containing the conductive particles made of silver and the diethylene glycol diethylether solvent (dispersion medium) is discharged. After the droplets are discharged, the drying process is preformed in order to remove the dispersion medium if required. The drying process can be performed by a commonly used heating means to heat the substrate P, for example, a hot plate and an electric furnace. In this embodiment, the heating conditions are for example 180° C. for about 60 minutes. This heating is not necessarily performed in the air but can be performed in the nitrogen gas atmosphere and the like.

This drying process can also be performed by the lamp annealing. As the light source of the lamp annealing, the above-mentioned ones used in the intermediate drying process after the first electrode layer formation process can be used. The power of the heating can also be in the range of above 100 W and below 1000 W.

Baking Process

The dispersion medium should be completely removed from the dried film after the discharged process in order to improve the electric contact among conductive particles. In case that the surface of the conductive particle is coated with an organic coating agent and the like in order to improve the dispersibility in the solution, this coating should be removed. For this purpose, the substrate after the discharge process is treated with heat and/or light. Conditions of this heat and/or light treatment can be the same as those of the above described baking process in the formation of the gate electrode 80.

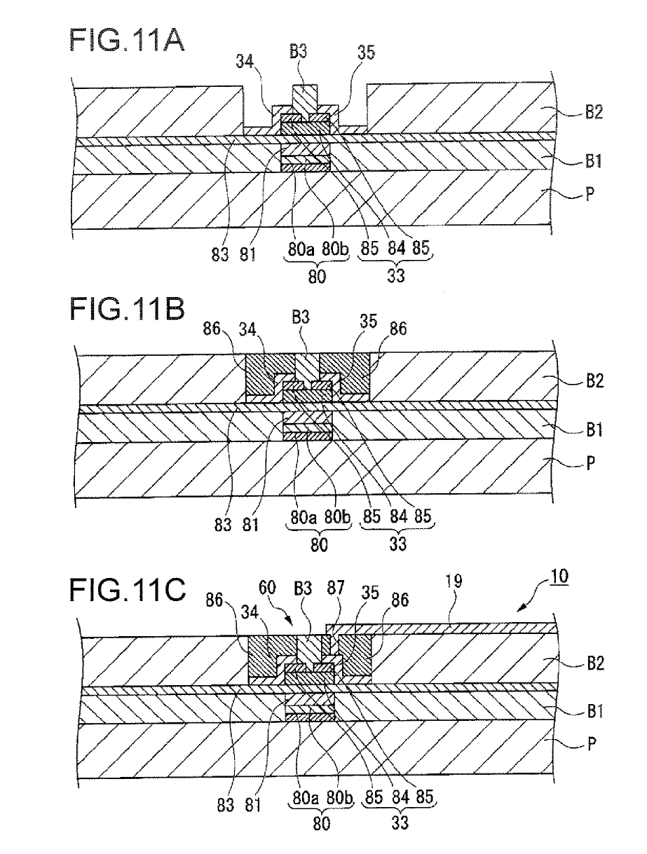

By conducting the above-described processes, the dried film after the discharge process turns into the conductive film in which the electric contact is secured among the particles, and the source electrode 34 which conductively couples with one N⁺ silicon layers 85 and the drain electrode 35 which conductively couples with the other N⁺ silicon layers 85 as shown in FIG. 11A are formed.

Next, the insulating material 86 is provided in a concave portion (opening) defined by the second banks B2, B3 and in which the source electrode 34 and the drain electrode 35 are formed so as to fill the concave portion (opening) as shown in FIG. 11B.

Next, the contact hole 87 is formed in the insulating material 86 where is closed to the drain electrode 35 as shown in FIG. 11C. Subsequently, a transparent electrode layer made of ITO and the like is formed by a liquid phase method such as the droplet discharge method (ink-Jet method) or a gas phase method such sputtering and a vapor deposition method, and then it is patterned if required to form the pixel electrode 19.

In any step of the above-mentioned processes, the substrate P is aligned with reference to the result of observation of the above-mentioned alignment mark AM.

Through the above described processes, the TFT 60 according to the embodiment of the invention is formed on the inner side (the upper side in the figure) of the glass substrate P, and the TFT array substrate 10 having the film structure including the pixel electrode 19 and the TFT can be obtained.

As described above, this embodiment forms the alignment mark AM having a low transparency is formed in the opening 31 of the first bank B1. Therefore, it is possible to recognize the alignment mark AM with a high recognition accuracy. Accordingly, it is possible to accurately align the substrate P with the droplet discharge head 301 and the mask used in the photolithography process and the like according to the embodiment. As a result, the patterns of the gate electrode 80, the semiconductor layer 33 and the like can be formed with a high precision.

Furthermore, the patterns overlaid on the substrate P are formed by using the same alignment mark AM in this embodiment. This makes it possible to improve the accuracy to overlay the pattern (wirings such as the gate electrode 80 and the semiconductor layer 33) formed in each layer.

Moreover, the alignment mark AM is made of the same material as that of the first electrode layer 80a formed by the droplet discharge method right after the formation of the alignment mark AM in this embodiment. Therefore, a preparation work such as ink change is not necessary and this improves the manufacturing efficiency as well as prevents the contamination of the ink. In addition, the same bank B1 is used in the formation of the alignment mark AM and the gate electrode 80 (the scan line 18a) in the same manufacturing process according to the embodiment. This can further improve the manufacturing efficiency.

Furthermore, the first electrode layer 80a is formed of a material having a higher adhesion with the substrate P than that of the second electrode layer 80b according to the embodiment. Accordingly, it is possible to form the gate electrode 80 which has the high adhesion with the substrate P and a defect such as coming off from the substrate is not likely to occur.

Next, a plasma type display device is described as an example of the electrooptical device of the invention.

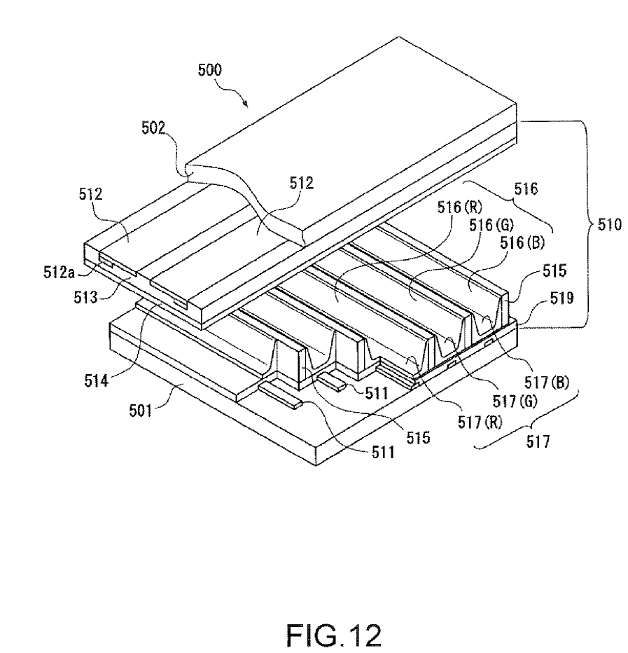

FIG. 12 is an exploded perspective view of a plasma type display device 500 of this embodiment.

The plasma type display device 500 includes glass substrates 501, 502 that oppose each other and an electric discharge display part 510 formed between the glass substrates 501, 502.

Address electrodes 511 are formed in a stripe form with a predetermined space therebetween on the upper face of the glass substrate 501 A dielectric layer 519 is formed so as to cover the upper faces of the address electrodes 511 and the glass substrate 501. A partition wall 515 is formed between two address electrodes 511, 511 so as to extend along the address electrode 511 on the dielectric layer 519. A fluorescent material 517 is provided in a strip area defined by the partition walls 515. The fluorescent material 517 produces a fluorescence light colored in one of red, green and blue. A red fluorescent material 517 (R) is provided on the bottom and the side faces of a red discharge room 516 (R), a green fluorescent material 517 (G) is provided on the bottom and the side faces of a green discharge room 516 (G), and a blue fluorescent material 517 (B) is provided on the bottom and the side faces of a blue discharge room 516 (B).

A display electrode 512 which is a plurality of transparent conductive films formed in a stripe form in the direction orthogonal to the direction where the address electrodes 511 extends with a certain space therebetween is formed on the glass substrate 502. A bus electrode 512a supporting the display electrode 512 that has a high resistance is formed on the display electrode 512. A dielectric layer 513 is formed so as to cover the above-mentioned elements and a protection film 514 made of MgO and the like is further formed.

The glass substrate 501 and the glass substrate 502 are adhered together so as to oppose each other in such a way that the address electrodes 511 orthogonally cross the display electrodes 512.

The electric discharge display part 510 includes a plurality of the discharge rooms 516. One pixel is an area surrounded by a group of three discharge rooms 516, that are the red discharge room 516 (R), the green discharge room 516 (G) and the blue discharge room 516 (B), and a pair of the display electrodes.

The address electrodes 511 and the display electrodes 512 are coupled to an unshown alternating current (AC) source. The fluorescent material is excited and emits light in the electric discharge display part 510 when current is applied to each electrode. In this way, a color display is realized.

In this embodiment, the bus electrode 512a and the address electrodes 511 are formed by the above described patterning method. Accordingly, the adhesion of the bus electrode 512a and the address electrodes 511 are high and defects in the wiring are hardly happened. In addition, these elements are aligned with a high precision. It is also possible to densely provide wirings because the accurate alignment of the wirings is possible. An alignment mark is formed by the droplet discharge method so that the formation process is much simpler relative to that of the photolithography technique and it is possible to reduce the production cost of the device.

Where the interlayer is made of a manganese compound (manganese oxide), a necessary electric conductivity between the display electrodes 512 and the bus electrode 512a can be secured by making the manganese layer very thin and porous even though the manganese oxide is not conductive. In this case, the interlayer shows a color of black. Such interlayer can serve like a black matrix and this can improve the display contrast.

Next, specific examples of electronic equipment of the invention are described.

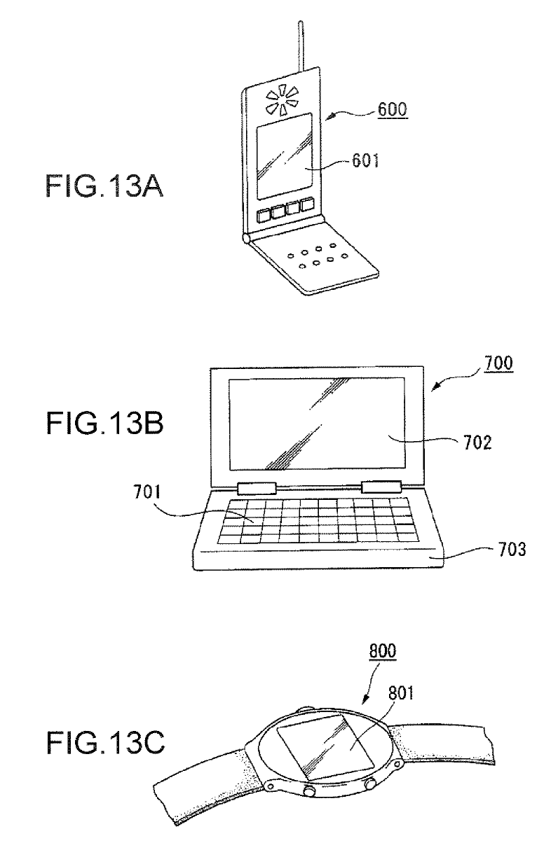

FIG. 13A is a perspective view of a mobile phone as an example. In FIG. 13A, reference numeral 600 refers to a body of the mobile phone and reference numeral 601 refers to a liquid crystal display part in which the above-described liquid crystal device is employed.

FIG. 13B is a perspective view of a portable information-processing device such as a word processor and a personal computer as an example. In FIG. 13B, reference numeral 700 refers to the information-processing device, reference numeral 701 refers to an input unit such as a keyboard, reference numeral 703 refers to a body of the information-processing device, and reference numeral 702 refers to a liquid crystal display part in which the above-described liquid crystal device is employed.

FIG. 13C is a perspective view of watch type electronic equipment as an example. In FIG. 13C, reference numeral 800 refers to a body of the watch and reference numeral 801 refers to a liquid crystal display part in which the above-described liquid crystal device is employed.

The electronic equipment showed in FIGS. 13A through 13C have the liquid crystal display devices of the embodiment as a display means. Therefore, it is possible to obtain high quality electronic equipment.

Though the electronic equipments of the embodiment have the liquid crystal device, it can have other electrooptical device such as an organic electroluminescence display device and a plasma type display device instead.

Although the embodiments of the invention have been fully described by way of example with reference to the accompanying drawings, it is to be understood that the embodiments described above do not in any way limit the scope of the invention. Configuration or combination of the above-mentioned members in the embodiments is just an example, and various changes and modifications will be applied within the scope and spirit of the invention in compliance of demands.

For example, though the droplet discharge process for forming the alignment mark AM is separated from the droplet discharge process for forming the first electrode layer 80a in the above described embodiment, these processes may be performed in one process in order to improve the manufacturing rate.

Though the wiring pattern has two layered structure of the first electrode layer 80a and the second electrode layer 80b in the above described embodiment, the wiring pattern can be made of a single layer or a multilayered structure of more than two layers. Where the pattern is the multilayered structure of more than two layers, it is preferable that a layer having a most strong adhesion with the substrate be placed as the first layer (or closest to the substrate). This is because the adhesion between the substrate and the pattern can be increased in this way and the defect of coming off will less occur.

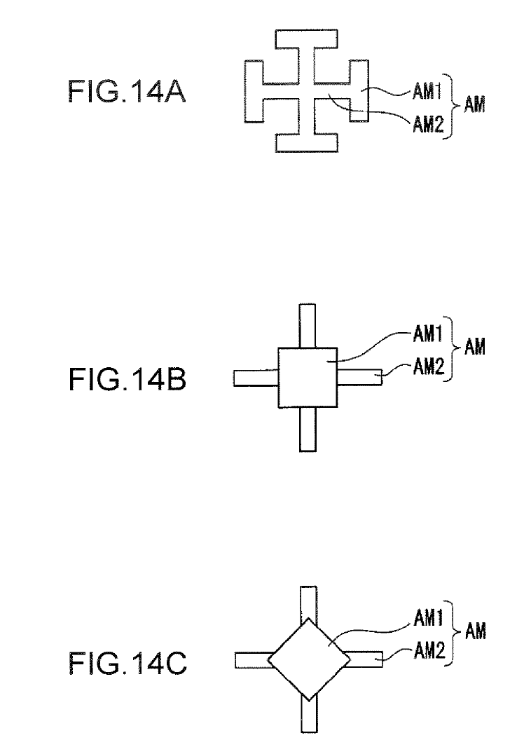

Though the configuration of the alignment mark AM is the cross shape when viewed in plan in the above described embodiment, the configuration can be other shapes. For example, the alignment mark AM can be made of two parts such as a larger part AM1 which has a wide width and a smaller part AM2 which has a narrow width as shown FIGS. 14A through 14C.

In this case, droplets can be discharged into the larger part AM1 and then the droplets can autonomously flow into the smaller part to fill there. In this way, it is possible to shorten the time to provide the droplets.

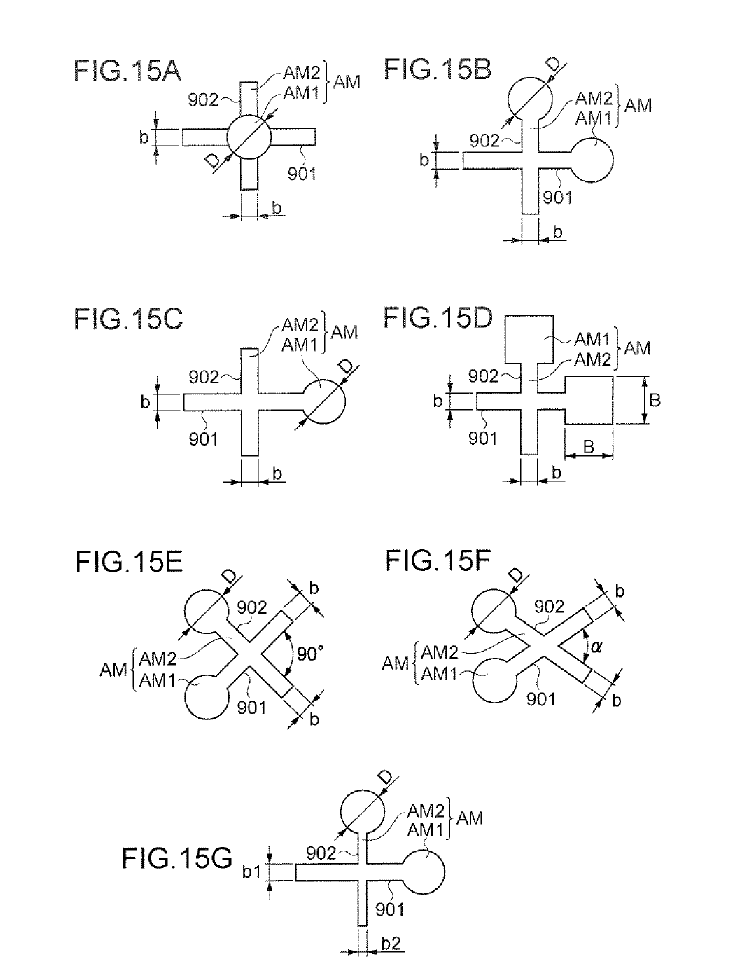

The alignment mark AM may have other configurations. Such configurations are for example shown in FIGS. 15A through 15G. As shown in FIG. 15A, a first line pattern 901 crosses a second line pattern 902. The alignment mark AM is composed of the larger part AM1 which has a wide width and a smaller part AM2 which has a narrow width. In this case, the larger part AM1 is the landing point of the droplets. Here, the size of the smaller part AM2 is denoted as a width “b” and the size of the larger part AM1 is denoted as a diameter “D”. The diameter “D” is larger than (>) the width “b” as shown in the figure. The length of the smaller part AM2 is decided according to the surface property (wettability) of the glass substrate P. When the wettability of the glass substrate P is fine (shows a high hydrophilicity), the length of the smaller part AM2 will be long. Contrary, when the wettability of the glass substrate P is not fine (shows a high hydrophobicity), the length of the smaller part AM2 will be short. It is possible to judge whether a desired surface treatment is performed to the surface of the glass substrate P or not from the length of the smaller part AM2. This judgment can be further used to decide whether drawing on the glass substrate P can be subsequently performed or not. If the surface condition of the glass substrate P is as fine as desired, the drawing can be subsequently carried out. If the surface condition of the glass substrate P is not yet fine, the drawing can be suspended and the substrate can be reproduced. In this way, it is possible to prevent the material from being wasted and to perform a wasteful work. The alignment mark shown in FIG. 15B has two landing points of the droplets, and the first line pattern 901 crosses the second line pattern 902. The alignment mark has two larger parts AM1 which are wide and two smaller parts AM2 which are narrow. The alignment mark shown in FIG. 15C has one landing point of the droplets, and the first line pattern 901 crosses the second line pattern 902. The alignment mark has one wide larger part AM1 and two narrow smaller parts AM2. The alignment mark shown in FIG. 15D has two landing point of the droplets that have a rectangular shape, and the first line pattern 901 crosses the second line pattern 902. The alignment mark has two larger parts AM1 that are formed in a wide rectangular shape and two smaller parts AM2 that are formed in a narrow rectangular shape. Here, the size of the smaller part AM2 is denoted as a width “b” and the size of the larger part AM1 having the rectangular shape is denoted as a width “B”. The alignment mark shown in FIG. 15E has two landing points of the droplets, and the first line pattern 901 crosses the second line pattern 902. The alignment mark has two larger parts AM1 which are wide and two smaller parts AM2 which are narrow. As shown in the figure, the alignment mark AM is arranged diagonal to the side face of the substrate when viewed in plan. The alignment mark shown in FIG. 15F has two landing points of the droplets, and the first line pattern 901 crosses the second line pattern 902. The alignment mark has two larger parts AM1 which are wide and two smaller parts AM2 which are narrow. The angle a between the first line pattern 901 and the second line pattern 902 is smaller than 90° as shown in the figure. The alignment mark shown in FIG. 15G has two landing points of the droplets, and the first line pattern 901 crosses the second line pattern 902. The alignment mark has two larger parts AM1 which are wide and two smaller parts AM2 which are narrow. The width “b2” of the second line pattern 902 is smaller than the width “b1” of the first line pattern 901 as shown in the figure. Meanwhile, as for the material for the alignment mark, a material having a high reflectivity can be used since the reflection rate of illumination light can be made high, making the contrast higher when it is imaged by a CCD camera and the like. In this way, it is preferable that the material forming the alignment mark is adequately selected based on imaging properties of the imaging means.

Technical ideas encompassed in the above described embodiments will be hereinafter described.

First Technical Idea

According to the patterning method described any of Claims 1 through 11, the patterning method forms the alignment mark having the first line pattern and the second line pattern that crosses the first line pattern.

In this way, the alignment can be easily done by utilizing the first line pattern 90l and the second line pattern 902 because the first line pattern 901 is provided so as to cross the second line pattern 902.

Second Technical Idea

According to the patterning method described any of Claims 1 through 11, the patterning method forms the alignment mark having the first line pattern and the second line pattern that crosses the first line pattern, and the width of the first line pattern and the width of the second line pattern are smaller than the size of the droplet landing area.

In this way, the alignment can be precisely performed by utilizing the first line pattern 901 and the second line pattern 902 because the width “d” is smaller than the diameter “D” of the larger part AM1 which is the landing point of the droplets. Consequently, it is possible to provide the liquid crystal display device 100 with a good quality.

Third Technical Idea

According to the patterning method described any of Claims 1 through 11, the patterning method forms the alignment mark having the first line pattern and the second line pattern that crosses the first line pattern, and the width of one of the first line pattern or the second line pattern is made narrower than the other.

In this way, it is possible to handle wiring patterns with various widths by making the width of one of the first line pattern or the second line pattern narrower. Consequently, it is possible to provide various kinds of the liquid crystal display device 100.

What is claimed is:

1. A method of forming a pattern, comprising:
forming mark partition walls that correspond to an alignment mark on a substrate before forming the pattern by providing a pattern forming material between partition walls; and
providing a liquid material containing an alignment mark forming material between the mark partition walls.

2. The method of forming a pattern according to claim 1, further comprising:
performing a surface treatment of the substrate.

3. The method of forming a pattern according to claim 2, further comprising:
judging an appropriateness of the surface treatment by measuring a length in which the liquid material containing the alignment mark forming material provided between the partition walls extends.

4. The method of forming a pattern according to claim 1, wherein the partition walls and the mark partition walls are formed in a same process.

5. The method of forming a pattern according to claim 1, wherein the pattern includes a first pattern and a second pattern that is made of a different material from a material forming the first pattern, and the first pattern and the second pattern are formed in layers.

6. The method of forming a pattern according to claim 5, wherein the alignment mark is formed of a same material as the material forming the first pattern.

7. The method of forming a pattern according to claim 6, wherein the alignment mark is formed in a same process in which the first pattern is formed.

8. The method of forming a pattern according to claim 5, wherein the first pattern is made of a material having a higher adhesion with the substrate than a material forming the second pattern.

9. The method of forming a pattern according to claim 1, wherein the pattern is a wiring pattern.

10. The method of forming a pattern according to claim 1, further comprising:
forming a pixel electrode by using the alignment mark.

11. The method of forming a pattern according to claim 1, further comprising:
forming a semiconductor layer by using the alignment mark.

12. A film structure comprising a pattern formed by the method of forming a pattern according to claim 1.

13. An electrooptical device comprising the film structure according to claim 12.

14. Electronic equipment comprising the electrooptical device according to claim 13.
